(19) United States
(12) Patent Application Publication
(10) Pub. No.: US 2018/0327271 A1
(43) Pub. Date: Nov. 15, 2018

(54) CHEMICAL VAPOR DEPOSITION METHOD AND APPARATUS

(71) Applicant: GTAT Corporation, Merrimack, NH (US)

(72) Inventors: Daniel J. DesRosier, Missoula, MT (US); Chad R. Fero, Missoula, MT (US)

(21) Appl. No.: 15/776,599

(22) PCT Filed: Nov. 14, 2016
(86) PCT No.: PCT/US16/61758

§ 371 Date: May 16, 2018

Related U.S. Application Data
(60) Provisional application No. 62/255,678, filed on Nov. 16, 2015.

(51) Int. Cl. C01B 33/035; C23C 16/24; C23C 16/44

(52) U.S. Cl. CPC C01B 33/035; C23C 16/4418; C23C 16/24

(57) ABSTRACT

A method of forming a filament assembly of a chemical vapor deposition (CVD) reactor, comprising at least one filament structure connected by a bridge, is disclosed. The filament structure comprises a hollow silicon filament integral with a silicon seed. Various embodiments of this invention are described, along with a CVD system comprising this filament assembly as well as a method of depositing silicon onto this filament assembly.

### CROSS-REFERENCE TO RELATED APPLICATIONS

This application claims the benefit of U.S. Provisional Patent Application Ser. No. 62/255,678, filed Nov. 16, 2015. The entire contents of this application are hereby incorporated by reference herein.

### BACKGROUND OF THE INVENTION

### 1. Field of the Invention

The present invention relates to a method and apparatus for chemical vapor depositions of silicon onto a hollow filament.

### 2. Description of the Related Art

Chemical vapor deposition (CVD) is a process used to produce high-purity, high-performance solid materials and is often used to produce high quality silicon for use in the semiconductor and photovoltaic industries. In a general conventional CVD process, a substrate material is exposed to one or more volatile precursors that react and/or decompose on the substrate surface to produce the desired material deposit. Frequently, volatile byproducts are also produced, which can be removed by gas flow through a reaction chamber in the CVD reactor.

One method to produce solid materials such as polysilicon is known as the Siemens method. In a typical Siemens-type polysilicon CVD reactor, a bell jar, such as a quartz bell jar, is secured to a base plate, forming a reaction chamber. The chamber contains a plurality of filaments, often in a hairpin or inverted U-shaped configuration having two vertical filaments connected by a horizontal bridge. Electrical feedthroughs and a gas inlet and outlet are also incorporated into the base plate. The filament assemblies are heated by passing electrical current through them and are exposed to a silicon-containing gas comprising, for example, monosilanes or chlorosilanes, thereby causing silicon to be deposited onto the filaments. For the production of high quality polysilicon, gaseous silicon compounds are introduced into the Siemens reactor and are pyrolytically decomposed in the presence of one or more high-purity thin silicon rods, sometimes referred to as slim rods, which are heated to an elevated temperature to enable silicon deposition. Typically, electrical current is passed through the slim rods to raise their temperature to approximately 1000° C. and in some cases to a temperature as high as 1200° C.

Because these slim rods are fabricated from high-purity silicon, the corresponding electrical resistance of the slim rods at room temperature is extremely high. Thus, a very high initial voltage is required to initiate the electric current during the startup phase of the polysilicon CVD process. Due to this high voltage, a small current can begin to flow through the slim rods. This current generates heat in the slim rods, reducing the electrical resistance of the rods, and permitting yet higher current flow, which generates additional heat. As the rods heat up to the desired temperature, the applied voltage is correspondingly reduced in order to avoid overheating and failure of the filament.

Connections within the filament assemblies are important in order to maintain proper electrical flow and minimize points of high resistivity, causing hot spots. Various types of connections between vertical filaments and a horizontal bridge are known, including, for example, a groove or a key slot at the top of each vertical rod configured to receive the bridge. A small counter bore or conforming segment can be formed on the ends of the horizontal bridge so that it can be press fitted into the grooves to bridge the two vertical slim rods.

Hollow filaments, such as tubular filaments, have also been used for polysilicon production and provide several advantages over traditional slim rod filaments. For example, due to the higher surface area of the tubular filaments, silicon is deposited at a faster rate. Furthermore, under ideal conditions, an increased overall surface area is available for connecting the tube filament and the bridge, and various types of connections are known. For example, a flat horizontal bridge can be used with a hollow tubular filament in order to increase the area for connection so that the total resistance that must be initially overcome is lower. U.S. Patent Application Publication Nos. 2011/0203101 and 2015/0211111 show various examples of connections between tubular filaments and flat horizontal bridges. However, such designs can sometimes suffer inconsistent resistivities in practice from non-ideal placement of the filament top against the bridge. For example, hollow filaments may not be cut exactly flat or perpendicular to their centerlines and/or the contact area of the bridge may not have an ideal surface. Alternatively, a cap positioned at the top of the hollow filament has also been shown, the cap having an opposite end configured to connect with the bridge. Typically the cap is a graphite cap. However, this design increases the total number of overall contacting surfaces, increasing the likelihood of restricting electrical current flow across the filament-bridge connection. In addition, as a practical issue, obtaining a consistent and tight fit of the cap to the hollow filament is often extremely difficult due to practical issues in the fabrication processes, and loose fits are common. Furthermore, mechanical strength may also be an issue for either types of design, which can lead to filament failure.

Thus, while the connection between hollow filaments and the corresponding bridge is improved compared to a slim rod filament, there remains a need to provide filaments having improved electrical and mechanical connectivity by minimizing the overall points of contact between the filament and the bridge.

### SUMMARY OF THE INVENTION

The present invention relates to a method of forming a filament assembly of a chemical vapor deposition system. The method comprises the steps of providing an electrically conductive bridge comprising at least one filament contact and providing a silicon seed having a first end and a second end. The first end of the silicon seed comprises a protrusion configured to grow a hollow silicon filament thereon, and the second end of the silicon seed is configured to mate with the filament contact of the bridge. The method further comprises the steps of contacting the protrusion on the first end of the silicon seed with molten silicon in a shaping dye of a crystal growth apparatus, the protrusion of the silicon seed and the shaping dye having substantially similar cross-sectional shapes; forming a filament structure comprising the hollow silicon filament on the first end of the silicon seed; and connecting the filament structure to the electrically conductive bridge by mating the second end of the silicon seed with the filament contact of the bridge. Preferably the crystal growth apparatus is an EFG crystal growth apparatus. The present invention further relates to a chemical vapor deposition system comprising at least one filament assembly having a pair of vertical filament structures formed by this method as well as to a method of depositing silicon onto this filament assembly.

It is to be understood that both the foregoing general description and the following detailed description are exemplary and explanatory only and are intended to provide further explanation of the present invention, as claimed.

### BRIEF DESCRIPTION OF THE DRAWINGS

FIG. 1A is a cross-sectional view of an embodiment of a filament assembly prepared and used in the methods and system of the present invention.

FIG. 1B is a top view of the bridge and FIG. 1C is a cross-sectional view of the seed of the filament assembly of FIG. 1A.

FIG. 2 shows an embodiment of the method of forming the filament assembly prepared and used in the methods and system of the present invention.

### DETAILED DESCRIPTION OF THE INVENTION

The present invention relates in general to silicon chemical vapor deposition methods and systems as well as to methods of forming CVD components.

In particular, the present invention relates to a method of forming a filament assembly for a chemical vapor deposition system. The filament assembly comprises at least one filament structure and an electrically conductive bridge. Preferably, the filament assembly has two vertical hollow silicon filament structures with a horizontal bridge connecting the two, the bridge providing both electrical contact and mechanical support. As such, the filament assembly preferably has a hairpin or inverted U-shaped configuration, with the electrically conductive bridge positioned on top of the two vertical filament structures. At least one, and preferably both, of the filament assemblies are produced using the method of the present invention.

The hollow filament of the filament structure is, in general, a high surface area filament, having a larger available surface for silicon deposition than a corresponding conventional solid slim rod filament. As such, the hollow filament can have a variety of different cross-sectional shapes depending, for example, on the desired CVD system and method used. For example, the hollow filament may have a circular or annular cross-sectional shape, or can have a square, rectangular, triangular, or other polygonal overall cross-sectional shape. The thickness of the hollow filament can be selected so that the electrical resistance of the hollow filament is the same as the conventional solid slim rod. In addition, the hollow silicon filament shapes can be either uniform or non-uniform along its length, varying in shape and/or thickness from one end of the filament to the other, but is preferably of uniform shape and thickness. Preferably the hollow filament is a cylindrical tubular filament. Furthermore, while hollow filaments may be preferred, it is also within the scope of the present invention that the filament structures comprise non-hollow filaments, also having surface areas higher than conventional solid slim rods, may also be used. Such filaments are generally described in U.S. Pat. No. 8,647,432, which is incorporated by reference herein.

The filament structure further comprises a silicon seed joined to the silicon filament and is formed by growing the hollow filament directly onto the seed. As such, the hollow silicon filament is fused to and in direct physical contact with the silicon seed from which it is grown. Thus, the filament structure comprises a silicon seed integral with a hollow silicon filament. This is in direct contrast to previously described connection designs used for high surface area filament for silicon deposition in a CVD reactor in which, for example, a cap is placed over the top of the filament. Such a cap, from a practical standpoint, is not in direct contact with the filament at all points along the connecting region, leading to poorer electrical flow. Additives may be used to seal the relatively loose connection, but this introduces impurities into the CVD process as well as increases the cost of silicon production. The filament structure of the present invention comprises an integrated seed-hollow filament connection, which provides significant improvements electrically and mechanically as well as in product quality and cost.

The seed of the filament structure has a first end on which the hollow silicon filament is grown and a second end configured for connecting to the electrically conductive bridge, described in more detail below. The first end of the seed is configured for filament growth and comprises at least one structural feature or element capable of being used to form a hollow filament of the desired shape and size. For example, the first end of the silicon seed can comprise at least one protrusion from which the filament is grown. The protrusion is a portion of the seed that is raised from the surface of the first end of the seed. As a specific example, the protrusion can be a lip around the perimeter of the first end of the silicon seed, providing a raised surface surrounding an inner cavity. The hollow silicon filament can be grown on the raised lip, forming an integrated seed-hollow filament combination. The thickness of the lip can vary depending, for example, on the desired thickness of the hollow filament and on the method of growth used. Other designs are also possible depending, for example, on the specific features of the desired hollow filament and will be known to one of ordinary skill in the art, given the benefit of the present disclosure.

The filament structure of the present invention can be formed using any crystal known crystal growth method and apparatus capable of growing a hollow silicon filament onto a silicon seed. For example, the filament structure can be formed using an edge-defined film growth (EFG) method in which molten silicon is contained within a crucible, such as a quartz or graphite crucible, and a shaping dye is positioned over and in contact with the molten silicon. The shaping due can be prepared from any material known in the art that is stable to conditions for EFG crystal growth of silicon, including, for example, graphite or quartz. The dye fills with molten silicon by capillary action, providing a shaped melt surface that defines the shape of the hollow filament to be crystallized from the silicon melt upon contact with a silicon seed. Filament wall thickness tolerances can generally be held to within 10% of the target thickness in the axial direction using this EFG technique.

In the method of the present invention, the first end of the silicon seed contacts the shaped melt surface in the shaping dye. In particular, as discussed above, the first end of the silicon seed comprises a protrusion, and the protrusion contacts the molten silicon in the shaping dye, from which the integral hollow filament is grown. Preferably, the cross-sectional shape of the protrusion is substantially similar to the cross-sectional shape of the shaping dye. For example, the shaping dye can have a circular cross-sectional shape for forming a cylindrical vertical filament, and preferably the protrusion of the first end of the silicon seed also has a circular cross-sectional shape. However, other shape combinations and crystal growth methods will also be known to one of ordinary skill in the art, given the benefit of the present disclosure and drawings. For example, an EFG system can be used with multiple shaping dies fed by a common melt pool, where the dies may be the same or different, forming various filament cross-section geometries.

The silicon seed used in the method of the present invention further comprises a second end configured to mate with an electrically conductive bridge, preferably connecting the filament structure to a second filament structure, which can be prepared using the same or similar method. The bridge can be prepared using any known electrically conductive material, such as graphite or silicon, but is preferably a silicon bridge in order to avoid introducing impurities into the grown silicon product. Any electrically conductive bridge known in the art can be used, including, for example, a flat horizontal bridge rectangular silicon bridge

The bridge used in the method of the present invention comprises at least one filament contact at which the hollow filament or filaments join or attach to the bridge. In particular, the filament contact is configured to mate with the second end of the silicon seed of the filament structure, or vice-versa. Any contact design can be used depending, for example, on the shape and size of the second end of the silicon seed and the shape and size of the bridge. As a specific embodiment, the filament contact may be a hole in or through the bridge. The hole can have a variety of different shapes, such as a circular, oval, square, rectangular, or triangular, but is sized and shaped to mate with the second end of the silicon seed. As such, the second end can fit into or through the hole, depending on the depth, thereby electrically and mechanically connecting the filament structure to the bridge. For this specific embodiment, the second end of the silicon seed can have a tapered shape, such as a conical or frustoconical shape, increasing in diameter from the top of the seed towards the hollow silicon filament of the filament structure. The hole may also be corresponding tapered. Alternatively, the second end of the seed may have a cylindrical shape sized to fit into or through the hole and further comprising a step portion upon which the bridge can rest. In an additional embodiment, the bridge may comprise at least one filament contact upon which the second end of the silicon seed may lock into or onto. For example, the filament contact may be threaded, with the second end of the silicon seed configured to screw into or onto the threads. For any of these embodiment, it may be preferred that the second end of the silicon seed further comprise a vent hole, particularly for a filament structure comprising a hollow filament. Other designs and configurations enabling the second end of the silicon seed to mate with the filament contact of the electrically conductive bridge will be known to one of ordinary skill in the art, given the benefit of the present disclosure.

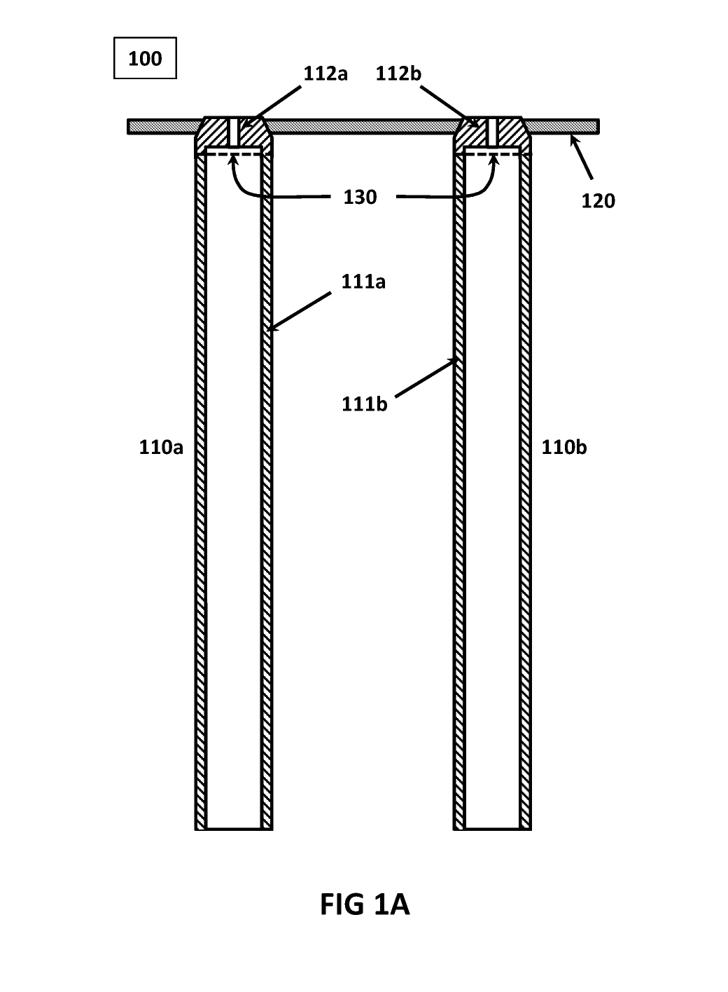

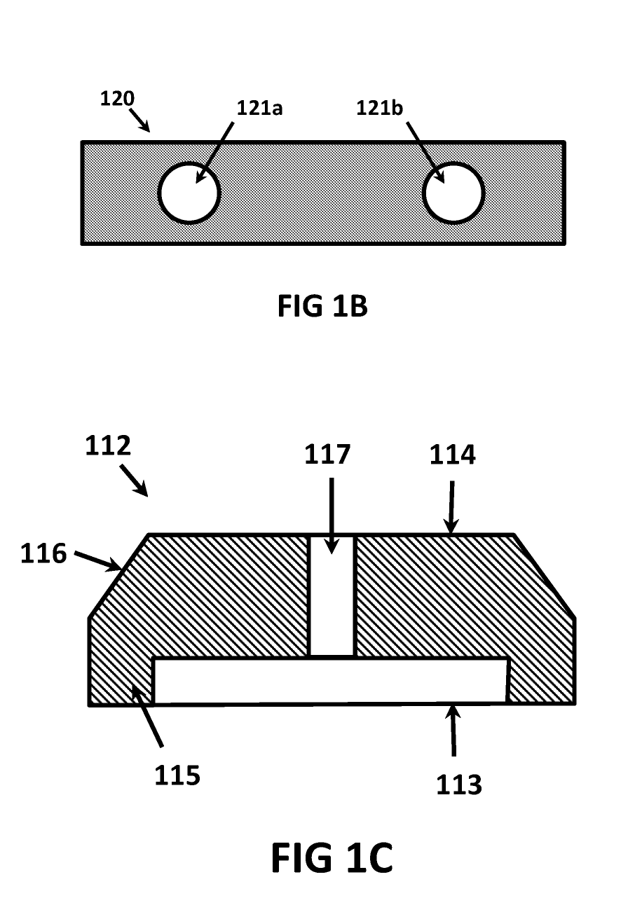

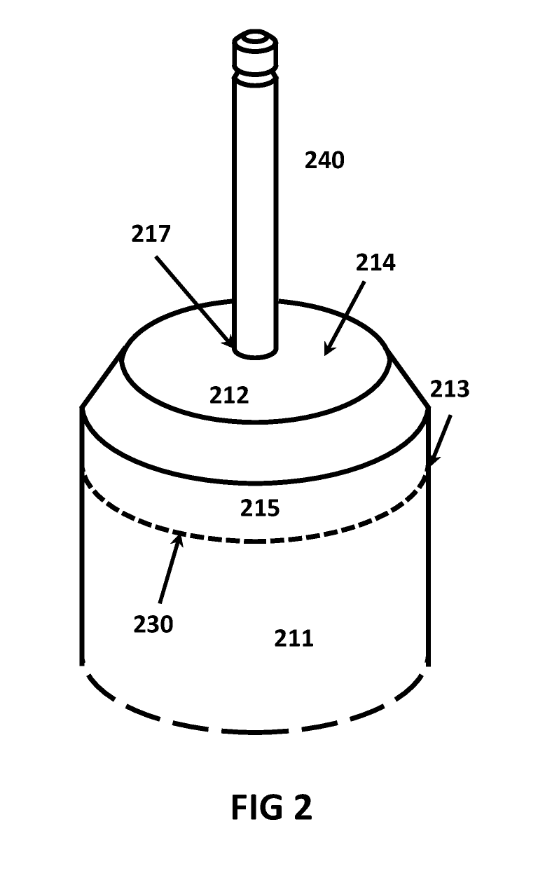

A specific example of the filament assembly formed in the method of the present invention, as well as components of the filament assembly, are shown in FIGS. 1A-C and FIG. 2. However, it should be apparent to those skilled in the art that these are merely illustrative in nature and not limiting, being presented by way of example only. Numerous modifications and other embodiments are within the scope of one of ordinary skill in the art and are contemplated as falling within the scope of the present invention. In addition, those skilled in the art will also be able to recognize and identify equivalents to the specific elements shown, using no more than routine experimentation.

As shown in FIG. 1A, filament assembly 100 comprises two vertical filament structures, 110a and 110b, connected by horizontal flat bridge 120, which is preferably a silicon bridge. The bridge is shown in more detail in FIG. 1B, as viewed from the top surface of the bridge. As shown, bridge 120 comprises two filament contacts, 121a and 121b, which are holes through the bridge. Each vertical filament structure comprises a hollow cylindrical tubular filament of silicon (111a and 111b) integral with a silicon seed (112a and 112b). Thus, each seed is fused to a filament along fusion boundaries 130. The seed, which has an overall cylindrical shape, is shown in more detail in FIG. 1C. As shown, seed 112 has first end 113 (shown as the bottom end of the seed) and second end 114 (shown as the top end of the seed), each configured for specific purposes. In particular, second end 114 is configured to mate with filament contacts 121a and 121b with section 116 having a frustoconical cross-sectional shape that fits into and projects through the contacts of the bridge. As seen most clearly in FIG. 1A, the filament contacts also have an angled interior surface that matches the taper of frustoconical section 116 in order to produce a mechanically tight and/or electrically consistent fit. Other configurations and fits are also possible. For example, the filament contact may have an unangled, vertically straight interior surface, which may be easier and less expensive to produce but would make contact only along the bottom edge of the contact with a fustoconically shaped first end of the seed. Furthermore, first end 113 of seed 112 comprises protrusion 115, which, as shown, is a raised lip along the outer perimeter of the first end and has the same cross-sectional shape as the filament. Seed 112 further comprises vent hole 117.

Formation of filament structure such as 110a and 110b is shown in FIG. 2. As shown, seed 212, comprising first end 213 and second end 214, is held by and supported by a seed holder of an EFG crystal growth apparatus, such as seed holder 240 which has been inserted into vent hole 217. The seed holder is lowered into contact with molten silicon contained within a shaping dye and is gradually withdrawn, forming hollow tubular filament 211, shown as having a circular cross-sectional shape resulting from the shape of the shaping dye. Also as shown, protrusion 215 has the same shape as the formed hollow filament. After reaching the desired length, the pulling is stopped, and the filament structure, comprising seed 212 integral with hollow filament 211 along fusion boundary 230, can be removed from seed holder 240 and vertically disposed within a chemical vapor deposition system along with a second formed filament structure, both being electrically connected to electrode chucks. The vertical filament structures can then be connected and supported with a bridge, such as flat horizontal bridge 120 shown in FIG. 1A and FIG. 1B.

Thus, the method of forming a filament assembly of a CVD reactor of the present invention comprises providing an electrically conductive bridge having at least one and preferably two filament contacts, providing a silicon seed having a first end configured to grow a hollow silicon filament thereon and a second end configured to mate with the filament contact(s) of the bridge, forming or growing a hollow filament on the first end of the silicon seed by contacting this end with molten silicon in a shaping dye of a crystal growth apparatus (such as by EFG), thereby forming one and preferably two filament structures, and connecting or joining the filament structure(s) to the electrically conductive bridge by mating the second end of the silicon seed to the filament contact(s). The present invention further relates to a chemical vapor deposition (CVD) system comprising this filament assembly as well as to a method of depositing silicon onto this filament assembly, and any of the embodiments described above can be used.

The foregoing description of preferred embodiments of the present invention has been presented for the purposes of illustration and description. It is not intended to be exhaustive or to limit the invention to the precise form disclosed. Modifications and variations are possible in light of the above teachings, or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

1. A method of forming a filament assembly of a chemical vapor deposition system, comprising the steps of:
i) providing an electrically conductive bridge comprising at least one filament contact;
ii) providing a silicon seed having a first end comprising a protrusion configured to grow a hollow silicon filament thereon and a second end configured to mate with the filament contact of the bridge;
iii) contacting the protrusion on the first end of the silicon seed with molten silicon in a shaping dye of a crystal growth apparatus, the protrusion of the silicon seed and the shaping dye having substantially similar cross-sectional shapes;
iv) forming a filament structure comprising the hollow silicon filament on the first end of the silicon seed; and
v) connecting the filament structure to the electrically conductive bridge by mating the second end of the silicon seed with the filament contact of the bridge.

2. The method of claim 1, wherein the method further comprises the steps of providing a second silicon seed having a first end comprising a protrusion configured to grow a second hollow silicon filament thereon and a second end configured to mate with a second filament contact of the bridge; contacting the protrusion on the first end of the second silicon seed with molten silicon in a shaping dye of a crystal growth apparatus, the protrusion second silicon seed and the shaping dye having substantially similar cross-sectional shapes; forming a second filament structure comprising the second hollow silicon filament on the second silicon seed; and connecting the second filament structure to the electrically conductive bridge by mating the second surface of the second silicon seed with the second filament contact of the bridge.

3. The method of claim 1, wherein the bridge is a silicon bridge.

4. The method of claim 1, wherein the filament contact is a hole through the bridge.

5. The method of claim 4, wherein the second end of the silicon seed fits through the hole, electrically connecting the filament structure to the bridge.

6. The method of claim 5, wherein the second end of the silicon seed is tapered, having a decreasing width in a direction away from the hollow silicon filament.

7. The method of claim 6, wherein the second end is frustoconical.

8. The method of claim 1, wherein the second end of the silicon seed is configured to lock onto the filament contact of the bridge.

9. The method of claim 8, wherein the filament contact and the second end of the silicon seed comprise mating screw threads.

10. The method of claim 1, wherein the hollow silicon filament is cylindrical.

11. The method of claim 10, wherein the cross-sectional shapes of the shaping dye and the protrusion are substantially circular.

12. The method of claim 1, wherein the protrusion is a raised lip around a perimeter of the first end of the silicon seed.

13. The method of claim 1, wherein the second end of the silicon seed further comprises a vent hole.

14. The method of claim 1, wherein the hollow silicon filament is integral with the silicon seed.

15. The method of claim 1, wherein the crystal growth apparatus is an EFG crystal growth apparatus.

16. A chemical vapor deposition system comprising at least one filament assembly having a pair of vertical filament structures electrically connected by a horizontal electrically conductive bridge, the bridge comprising a pair of filament contacts and the filament structures comprising a hollow silicon filament on a silicon seed,
wherein the silicon seed has a first end comprising a protrusion configured to grow the hollow silicon filament thereon and a second end configured to mate with the filament contacts of the bridge;

17. The chemical vapor deposition system of claim 16, wherein the hollow silicon filaments are integral with the silicon seeds.

18. A method of depositing silicon onto a filament assembly in a chemical vapor deposition system comprising the steps of introducing gaseous silicon precursor reagents into the chemical vapor deposition system and promoting conversion of the gaseous silicon precursors reagents to silicon on the filament assembly, wherein the filament assembly is formed by a method comprising the steps of:
i) providing an electrically conductive bridge comprising at least one filament contact;
ii) providing a silicon seed having a first end comprising a protrusion configured to grow a hollow silicon filament thereon and a second end configured to mate with the filament contact of the bridge;
iii) contacting the protrusion on the first end of the silicon seed with molten silicon in a shaping dye of a crystal growth apparatus, the protrusion of the silicon seed and the shaping dye having substantially similar cross-sectional shapes;
iv) forming a filament structure comprising the hollow silicon filament on the first end of the silicon seed; and
v) connecting the filament structure to the electrically conductive bridge by mating the second end of the silicon seed with the filament contact of the bridge.
